(19) United States
(12) Patent Application Publication
(10) Pub. No.: US 2020/0115228 A1
(43) Pub. Date: Apr. 16, 2020

(54) SYSTEMS, DEVICES, AND METHODS FOR DIRECT-WRITE PRINTING OF ELONGATED NANOSTRUCTURES

(71) Applicants: Crystal Elaine Owens, West Des Moines, IA (US); Gareth H. McKinley, Acton, MA (US); Anastasios John Hart, Waban, MA (US)

(72) Inventors: Crystal Elaine Owens, West Des Moines, IA (US); Gareth H. McKinley, Acton, MA (US); Anastasios John Hart, Waban, MA (US)

(21) Appl. No.: 16/653,977

(22) Filed: Oct. 15, 2019

Related U.S. Application Data
(60) Provisional application No. 62/745,753, filed on Oct. 15, 2018.

(51) Int. Cl. B81C 99/00; B81C 1/00

(52) U.S. Cl. CPC B81C 99/0015; B81C 1/00373; B82Y 40/00; B81C 2201/0184; B81C 2900/02

(57) ABSTRACT

The present disclosure is directed to tailoring the structure of freeform nanotube macrostructures through extrusion-based additive manufacturing for fabrication of planar and three-dimensional features and objects. Ink containing nanomaterials can be extruded into a fluid to precipitate into a fiber that can be used to form solid structures. The fluid can include a coagulant that promotes rapid solidification in the precipitation of fibers. The fluid can be disposed into a bath that is in fluid communication with the extruded ink. Systems and devices for executing such processes, are also provided.

### CROSS REFERENCE TO RELATED APPLICATION

The present disclosure claims priority to U.S. Provisional Application No. 62/745,753, entitled “Printing of Carbon Nanotubes in Fluids,” which was filed on Oct. 15, 2018, and which is incorporated by reference herein in its entirety.

### GOVERNMENT RIGHTS

This invention was made with Government support under Grant No. NNX17AJ32G awarded by NASA. The Government has certain rights in the invention.

### FIELD

The present disclosure relates to systems, devices, and methods for printing of elongated nanostructures, and more particularly relates to tailoring the structure of freeform nanomaterial macrostructures through extrusion-based additive manufacturing for fabrication of planar and three-dimensional features and objects.

### BACKGROUND

The growing role of technology in modern life, from smartphones to data centers to electric cars, has increased demand for electrical energy and underscores the need for more efficient methods of power generation, transmission, and conversion. Current methods experience resistive losses as a major source of inefficiency (˜25% of transmission losses, >50% of motor losses), which limits the performance of generation and conversion devices, such as electric motors, through the production of heat. Numerous specialized and complex methods for manufacturing these materials currently exist to enhance general availability, mass production, and scalability. For example, manufacturing processes using polymers have popularized a technique known as fiber spinning, which can create strong fibers, due to the enhanced control of the molecular structure and uniaxial alignment of polymer chains. Additionally, three-dimensional (“3D”) printing is growing in popularity as a way to produce objects, including but not limited to proposed applications in specialty electronics, power transformers, and aviation equipment.

There are multiple known techniques for printing three-dimensionally, such as non-extrusion-based processes like stereolithography and inkjet deposition, and extrusion-based processes like filament fabrication (FFF). While these techniques offer numerous benefits, such as allowing for high resolution printing, they suffer from a number of shortcomings. For example, many objects printed using known, traditional 3D-printing techniques produce parts that have poorer mechanical properties than those produced by traditional manufacturing processes, including fiber spinning. This is at least because the existing 3D-printing techniques are not as adaptable or configurable to easily provide a variety of properties across a surface area of the printed object (e.g., it is difficult to change the strength and/or flexibility of a printed object across a surface area of the object).

One example of such materials is carbon nanotubes (CNTs), which present an interesting building block for improved wires due to an individual CNT's higher electrical conductivity, thermal conductivity, current-carrying capacity, and superior strength when compared to metals. CNTs are hollow cylindrical macromolecules of carbon in a hexagonal lattice (and can be viewed conceptually as rolled-up sheets of graphene), with diameters approximately in the range of about 1 nm to about 50 nm and lengths typically approximately in the range of about 0.1 μm to about 10 μm. Due to CNT's small tubular structure, electrons in CNTs can move via ballistic transport (without scattering) along the length of a single-walled CNT (SWCNT), resulting in a significantly longer mean free path than in crystalline metals, and causing some of the enhanced properties. Due to the unique linear structure, CNTs also do not experience the inhibiting skin effect at high electrical frequencies that is observed in all metals, making CNTs particularly suitable for use in high-frequency wireless transmitters and receivers, as well as more efficient motors, high-current transmission lines, transformers, and circuit interconnects. In particular, compared to copper wiring, CNT wiring is projected to have a lower overall production cost, simpler processing, up to four orders of magnitude greater current carrying capacity, greater tensile strength, better corrosion resistance of the final wire, a higher thermal conductivity at elevated temperatures (accelerating cooling), and equivalent specific conductivity (e.g., conductivity per density). Remarkably, the electrical conductivity, thermal conductivity, current-carrying capacity, and strength of CNTs improves at higher temperatures where metals tend to lose performance. For example, the resistance of a copper wire will increase 15% when heated from 20 degrees to 60 degrees Celsius, while a typical CNT structure resistance would decrease 1% in the same range. When implemented in a fiber-spinning process, CNT fibers can typically be >100× stronger than pure-CNT cast films or composites, additionally showing higher conductivity per mass in the direction of spinning.

Despite these properties, which make CNTs ideal functional materials that combine the best properties of polymers, carbon fibers, and metals, CNTs have not been readily applied to real-world issues such as wiring for use in consumer electronics and long-range power transmission. Specifically, existing methods of working with, and manufacturing objects using, CNTs have several shortcomings. For example, the properties of individual CNT structures have, to date, not been replicated into macrostructures composed of bulk numbers of CNTs. In fact, bulk performance of CNTs has been limited to < 1/10 that of an individual CNT structure. Further, existing processes lack the granular control over using fibers to manufacture solid structures, resulting in structures that are oddly shaped or exhibit one or more of defects, poor contact area, and low density fraction that prevent optimization of the macrostructure.

Accordingly, there is a need to create systems, devices, and methods for a novel manufacturing approach for printing using CNTs where the resulting macrostructures have bulk CNT properties that approach those of individual CNT.

### SUMMARY

The systems, devices, and methods provided for in the present disclosure are directed to printing of elongated nanostructures with tunable local properties. The nanostructures can be used to print structures of highly aligned fibers that have bulk properties that approach those of individual nanostructures. Printing can occur via controlled drawing, which combines fiber-spinning techniques of materials with three-dimensional printing principles to form the fibers. In controlled drawing, a liquid ink is extruded through a printing device and precipitated into fibers to form a solid structure. In some embodiments, the printing device can be in fluid communication with a bath having a coagulant therein for precipitating fibers from the extruded ink. The coagulation bath can be part of the printing device itself, or it can be a separate component of a printing system in which the printing device extrudes the liquid ink therein. The printing device can include a controller configured to tune system parameters, such as a draw ratio, to regulate the shape and alignment of the material within the solid precipitate while the ink is forming the solid. In some embodiments, the ink and the coagulant can react within the nozzle such that a precipitated fiber is extruded therefrom.

One exemplary method of extruding inks having suspensions of at least one of elongated nano-particles or elongated micro-particles includes extruding an ink through a nozzle of a printing device into a fluid and onto at least one of a substrate, an object disposed on the substrate, or previously extruded ink. The ink in this method includes a mixture of at least one of nano-particles or micro-particles and a liquid. The fluid includes one or more materials. The method further includes moving the nozzle in one or more degrees of freedom with respect to the substrate while extruding the ink into the fluid, and the ink coagulating after it contacts the fluid such that the ink forms a solid precipitate.

The one or more materials can be immiscible with the nano-particles or micro-particles of the mixture and miscible with the liquid. Extruding the ink through a nozzle of the printing device into the fluid can include continuously dispensing ink such that the ink forms a continuous thread upon coagulation. The solid precipitate can be self-supporting. In some embodiments, the method can include adjusting one or more of a temperature, pressure, humidity, or oxygen content of at least one of the fluid or an environment surrounding the fluid.

The method can further include adjusting a draw ratio associated with the extruded ink such that the overall fiber diameter is controlled. In some embodiments, the draw ratio or other parameters can be adjusted such that the nanostructures can be substantially aligned in the direction of motion of the nozzle relative to the substrate. Alternatively, or additionally, adjusting the draw ratio can include adjusting at least one of a flow rate of the extruded ink, a temperature of the extruded ink, a velocity of the nozzle, or a velocity of the at least one of a substrate, an object disposed on the substrate, or previously extruded ink. The draw ratio can be approximately in the range of about 0.1 to about 10.

The method can further include an ink that contains carbon nanotubes. In some such embodiments, the fluid can include one or more of an alcohol, a ketone, or an acid. In some embodiments, the ink can contain cellulose nanocrystals, and the fluid can include a salt solution. In some embodiments, the ink can contain elongated nanostructures that are electrically conductive. The ink can contact the fluid within the nozzle. The method can further include controlling the shape and alignment of the material within the solid precipitate while the ink is forming the solid.

Another exemplary method of extruding inks that comprise suspensions of at least one of elongated nano-particles or elongated micro-particles includes extruding an ink through a nozzle of a printing device into a fluid bath. The ink includes at least one of nano-particles or micro-particles and a liquid. The fluid bath includes a coagulant disposed therein to solidify the ink to form an object. The method further includes moving the nozzle relative to the fluid bath to define a form of the object, and adjusting one or more of a velocity of the extruded ink through the nozzle or a velocity of the nozzle relative to the fluid bath.

The method can further include mixing the carbon nanotubes with the liquid to form the ink prior to extruding the ink through the nozzle. The ink can be extruded into the fluid bath continuously throughout the movement of the nozzle. In at least some embodiments, a diameter of the extruded ink can be smaller than a diameter of the nozzle from which the liquid is extruded. The diameter of the extruded ink can decrease as draw ratio decreases.

One exemplary embodiment of a printing system includes an extruder having one or more nozzles and a bath. The extruder is configured to dispense a liquid ink out of the one or more nozzles, with the liquid ink including a mixture of at least one of nano-particles or micro-particles and a solvent. The bath defines a volume in which a fluid is configured to be disposed in the bath. The bath is in fluid communication with the extruder such that the bath is configured to receive the liquid ink.

The system can include a controller configured to control a draw ratio of the liquid ink dispensed from the extruder. The controller can be configured to adjust at least one of a flow rate of the liquid ink, a velocity of the one or more nozzles, or velocity of a location disposed in the bath. Alternatively, or additionally, the system can include a controller (the same or a different controller than the previously identified controller) configured to control one or more of a temperature, humidity, or oxygen content of at least one of the bath, the fluid disposed in the bath, or an environment of or surrounding the bath. The location in this is instance is where the liquid ink is being dispensed to control the draw ratio of the liquid ink dispensed from the extruder. Further still, the system can include a controller (the same or a different controller(s) than the previous identified controller(s)) configured to toggle the extruder between an “on” configuration in which the one or more nozzles continuously dispense the ink from the nozzle(s), and an “off” configuration in which the one or more nozzles do not dispense ink from the nozzle(s). The nozzle(s) can be configured to dispense the ink continuously therefrom when toggled from the “off” configuration to the “on” configuration.

The extruder can be configured to dispense the ink out of the nozzle(s) in a continuous manner. The fluid can be configured to cause the liquid ink to coagulate to form a solid structure. The ink can include a shear-thinning fluid. In at least some embodiments, the ink can include a solution of carbon nanotubes in water that approximately ranges from about 0.1% by weight to about 0.9% by weight of carbon nanotubes relative to the total weight of the solution.

The system can further include a heating element disposed proximate to the nozzle(s) and configured to heat the ink being dispensed to maintain the ink in its liquid phase. In some embodiments, the fluid can be configured to be disposed within the nozzle(s) such that the liquid ink reacts with the fluid within the nozzle. In such embodiments, the nozzle(s) can be configured to control the shape and alignment of the material within the precipitate formed after the liquid ink reacts with the fluid.

### BRIEF DESCRIPTION OF DRAWINGS

This disclosure will be more fully understood from the following detailed description taken in conjunction with the accompanying drawings, in which:

FIG. 1A is a schematic perspective view of a prior art wet fiber spinning process;

FIG. 1B is a detailed perspective view of a bath of the wet fiber spinning process of FIG. 1A;

FIG. 1C is a perspective view of a fiber spinneret creating a parallel array of fibers from a spinning solution;

FIG. 2A is a schematic perspective view of one exemplary embodiment of a printing system;

FIG. 2B is a perspective view of an extruder of the printing system of FIG. 2A;

FIG. 2C is a schematic perspective view of one exemplary embodiment of a nozzle that can be used in conjunction with the printing system of FIG. 2A;

FIG. 2D is a schematic side view of a fully continuous printing process in which ink is extruded from a nozzle into a fluid bath of the printing system of FIG. 2A;

FIG. 2E is a schematic top view of coiling behavior of fibers at various draw ratios;

FIG. 3 is a graph illustrating a relationship of a radius of an extruded fiber and a draw ratio for fluids having varying coagulant strengths;

FIG. 4 is a graph illustrating an effect of coagulant strength and draw ratios on the rheology of extruded fibers;

FIG. 5 is a schematic side view of a nozzle illustrated at varying heights to illustrate an impact of height on solidification of layers of ink extruded from the nozzles;

FIG. 6 is a contour plot illustrating the variability of fiber diameter in response to coagulant strength of a destabilizing fluid and a draw ratio of printing systems of the present disclosure;

FIG. 7A is a schematic side view of a reaction-controlled, acid-supported printing process illustrating an extruded ink reacting with water vapor in an environment to solidify;

FIG. 7B is a perspective view of contents of the fiber printed by the reaction-controlled, acid-supported printing process of FIG. 7A;

FIG. 8 is a schematic side view of a temperature-controlled, acid-supported printing process illustrating an extruded ink undergoing a phase change when contacting a substrate; and

FIG. 9 illustrates a perspective view of one exemplary embodiment of a solid structure printed according to the printing processes described herein.

### DETAILED DESCRIPTION

Certain exemplary embodiments will now be described to provide an overall understanding of the principles of the structure, function, manufacture, and use of the systems, devices, and methods disclosed herein. One or more examples of these embodiments are illustrated in the accompanying drawings. Those skilled in the art will understand that the systems, devices, and methods specifically described herein and illustrated in the accompanying drawings are non-limiting exemplary embodiments and that the scope of the present disclosure is defined solely by the claims. The features illustrated or described in connection with one exemplary embodiment may be combined with the features of other embodiments. Such modifications and variations are intended to be included within the scope of the present disclosure.

To the extent a term like “fiber” is used herein without a structural modifier, a person skilled in the art, in view of the present disclosure, will understand that it includes a material extruded from a nozzle, a continuous, semi-continuous, or non-continuous pre-made fiber, or combinations thereof. Additionally, to the extent the terms “depositing” and “extruding” are described in the present disclosure, a person skilled in the art will recognize that “extruding” is one form of depositing a material, and that it typically involves ejecting a material from a nozzle, while “depositing” more generally describes a variety of ways by which a material can be printed. Further to the extent the terms “solidify” and “coagulate” are described in the present disclosure, though they are sometimes used interchangeably, a person skilled in the art will recognize that “coagulate” is a form of solidification in which a material is exposed to a coagulating substance or nonsolvent that causes the material to solidify, with the solidification occurring, for example, because the particles in the original ink, or particles stabilizing the particles of interest, are not soluble in the coagulant and precipitate out, and/or the coagulant reacts with the original ink to cause the material to solidify. While the present disclosure primarily describes depositing materials for printing via one or more nozzles, and thus primarily describes extruding, a person skilled in the art will recognize that the same techniques can be applied to other techniques for depositing materials during fiber spinning or 3D printing, including fused deposition modeling (FDM) or electrospinning. Accordingly, to the extent the term nozzle is used herein, a filament guide or other object used for depositing material can be used interchangeably or in conjunction with a nozzle.

Further, to the extent features, sides, or steps are described as being “first” or “second,” such numerical ordering is generally arbitrary, and thus such numbering can be interchangeable. Still further, in the present disclosure, like-numbered components of various embodiments generally have similar features when those components are of a similar nature and/or serve a similar purpose. Lastly, the present disclosure includes some illustrations and descriptions that include prototypes or bench models. A person skilled in the art will recognize how to rely upon the present disclosure to integrate the techniques, systems, devices, and methods provided for into a product in view of the present disclosures.

The present disclosure generally relates to systems, devices, and methods for printing of nanomaterials in fluids, and more particularly relates to a microfabrication process using carbon nanotubes (CNTs) to build three-dimensional structures with tunable local properties while enabling scale-up of nanomaterial properties to macroscale structures. Nanomaterials such as CNTs have higher ultimate tensile strength than Kevlar, higher thermal conductivity than silver, and electrical conductivity near that of copper, while having a low density, allowing it to form a lightweight material with an outstanding combination of mechanical strength and stiffness, electrical and thermal conductivity, and low density. The nanotube structures can be used to print solid structures in dense liquid solutions of colloidal particles. Further, as provided for herein, by using techniques that include spinning the CNTs into fibers, the CNTs can have higher strength than when bulk-formed into objects. The fibers better align themselves in extensional flow in a dense solution, allowing for rapid and precise printing of highly aligned nanotube structures. Accordingly, the present disclosure focuses on combining the strongly-aligning properties of an extensional fluid flow of CNT suspensions with wet-fiber spinning techniques within a microfluidic device to enable the continuous manufacturing of CNT fibers with high conductivity and strength.

An exemplary method of printing CNTs in fluid can include a controlled drawing process in which a liquid ink is extruded through a printing device and precipitated into fibers to form a solid structure. In controlled drawing, fiber-spinning techniques of materials can be combined with three-dimensional printing principles to form the fibers. The ink can be a mixture of CNTs and a solvent that passes through a modified printer to support extrusion of the mixture therethrough. The printing device can be configured to print onto a substrate, an object disposed on or otherwise associated with the substrate, and/or previously extruded ink. The substrate and/or previously extruded ink can be disposed in, surrounded by, and/or otherwise associated with a coagulation bath. The coagulation bath can be part of the printing device itself, or it can be a separate component of a printing system in which the printing device extrudes the liquid ink into the coagulation bath, the bath including the substrate and/or previously extruded ink onto which the ink is printed. In some embodiments, the extruded ink can be exposed to a destabilizing fluid that promotes coagulation of the extruded ink into pure CNT fibers to increase the packing density of bulk CNTs while separating the solvent therefrom. The printing device can also be used to tune system parameters, such as a draw ratio, to regulate the shape and radius of the extruded ink that will form the fibers of the solid structure.

A person skilled in the art will recognize that continuously dispensing and/or extruding ink from a nozzle in the case of the controlled drawing process refers to a process in which ink is actively extruded to precipitate a fiber for formation of solid structures. While the term “continuous” is used to describe this process, a person skilled in the art will understand that instances in which the nozzles stops and starts, or changes direction may be desirable, and thus the term “continuous” can encompass situations in which the nozzles finish extruding ink at a first location and migrate to a second location, where the nozzle stops extruding ink during said migration. Continuous extrusion, as provided in the present disclosure, can include a process in which extrusion stops for a time of up to 1000 seconds and/or a precipitated fiber having a length of equal to or greater than three times the inner diameter of the extruding nozzle, or typically greater than 500 micrometers, can be said to have been extruded continuously. A length of a precipitated fiber that has been extruded continuously should be sufficiently long such that the extruded ink that precipitates the fiber feels a tension that affects the alignment of the extruded ink as it is being pulled out of the nozzle, thereby having a non-negligible shear stress exerted thereon by a bath into which the ink is extruded. A person skilled in the art will appreciate that the extruded filament is not simply “deposited,” but rather “drawn” by the bath, which can impact the microstructure of the extruded ink, and distinguishes the instant process from inkjet-type printing. It will be appreciated that a minimum length of the precipitated fiber can depend, at least in part, on a viscosity of the bath and the composition of the ink.

Prior Art Printing Processes

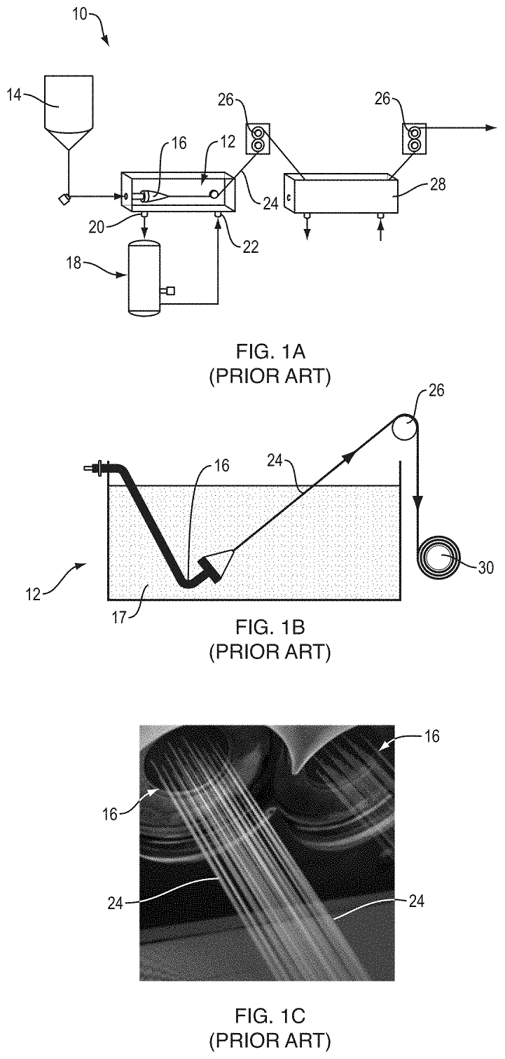

FIGS. 1A-1C illustrate a prior art wet fiber spinning process 10. As mentioned above, the fiber spinning process is a widely known general manufacturing strategy with polymers at least because the fiber spinning process is known to create a stronger material than bulk processes like molding or casting, when using the same starting material, due to the enhanced control of the molecular structure and uniaxial alignment of polymer chains. In CNTs, this has also been shown to be the case, where CNT fibers can be approximately >100× stronger than pure-CNT cast films or composites, while showing higher conductivity per mass in the direction of spinning. In wet fiber spinning, a material is extruded into a coagulant bath, coagulated to form a fiber, which then precipitates into a solid linear fiber. Applying wet fiber spinning processes to CNTs from a concentrated solution (i.e., CNTs dispersed in a superacid) with doping have been shown to produce linear fibers with electrical conductivity of at least about 500 S/cm and current-carrying capacity of at least about 10⁴ A/cm².

As shown in FIG. 1A, a wet fiber spinning process 10 includes a bath 12 fed by a feed tank 14. The bath 12 can include spinneret 16 therein for extruding a solution into the bath. The spinneret 16 can include one or more nozzles (not shown) from which the solution is extruded. The spinneret 16 can be configured to deliver the solution continuously or at specific time intervals. A person skilled in the art will recognize that the spinneret 16 remains stationary within the bath 12 and does not change its location relative to the bath.

The bath 12 can include a solidification medium 17 therein, illustrated in FIG. 1B, for coagulating the exposed solution released from the spinneret 16. Turning back to FIG. 1A, the bath 12 can be connected to a supply tank 18 that delivers the solidification medium to the bath 12 to be applied to the extruded solution. As shown, the bath 12 can have an exit port 20 for feeding the solidification medium back into the supply tank 18 for recycling and an inlet port 22 for introducing fresh solidification medium into the bath 12. In some embodiments, the feed tank 14 can provide compounds, such as polymers, to be added to the starting solution released from the spinneret 16 to strengthen the degree of solidification of the solution.

Once portions of the solution have solidified into a fiber 24 following contact with the solidification medium 17, as shown in greater detail in FIG. 1B, the fiber 24 can be removed from the bath 12 containing the coagulation medium 17 via one or more take-up wheels 26. For example, the fiber 24 can be removed from the bath 12 containing the coagulation medium 17 under tension and taken to a washing bath 28, as shown in FIG. 1A, for cleaning and removing the solidification medium and unwanted solvent therefrom. The spinneret 16 can then create a parallel array of fibers from the spinning solution to be taken by the take-up wheel 26, as shown in FIG. 1C. After running through the washing bath 28, another set of take-up wheels 26 can remove the fiber 24 from therefrom and deliver it for further treatment. Some non-limiting examples of such treatments can include baths, stretching apparatuses, drying apparatuses, and so forth. In some embodiments, the fiber can be spooled onto a roll 30, as shown in FIG. 1B.

Wet spinning methods can be used to develop CNT fibers with high degrees of conductivity, e.g., 20,000 S/cm (before doping), and specific conductivity (conductivity divided by density). The high conductivity values of the wet spinning method can be attributed to the high degree of control throughout the spinning process, such as allowing purification of the CNTs in the precursor solution, removal of residual catalyst left over from CNT production, and/or continuation into the processing of the CNTs. These levels of control allow influence of an alignment force on the CNTs at every location in the fiber forming process by manipulating the fluid flow. Wet spinning can also be a continuous process, and can accommodate adding fillers and dopants to the initial solution, such as polymers for enhanced strength, and/or functionalized CNTs for sensing, as discussed above.

CNT fibers can also be made by dry spinning. In this process, dry fibers are pulled from an aligned state, such as CNTs from a “forest.” One advantage of dry spinning would be producing fibers from the pristine as-grown CNT state, rather than temporarily suspending them into liquid. Yet another common method is electrospinning, which uses an electric field to jet a liquid as a continuous strand, and this process can achieve smaller fiber diameters than conventional wet and dry spinning.

However due to limited lengths (microns) and imperfect contact among the CNTs, the properties of even these macroscopic fibers woven from CNTs using fiber spinning have failed to achieve the same properties of individual CNTs. Further, electrical and mechanical properties of CNTs are interdependent but may have some competing microstructural needs. For example, high alignment will enhance conductivity but decrease mechanical strength (due to reduction in the number of tube-tube interactions), whereas entanglement will do the converse. As a result, the demonstrated mechanical, thermal, and electrical properties of these CNT-based fibers are orders of magnitude below what a single nanotube exhibits, indicating there is a large margin for improvement. Dry fiber spinning and electrospinning methods suffer from similar deficiencies.

Controlled Drawing

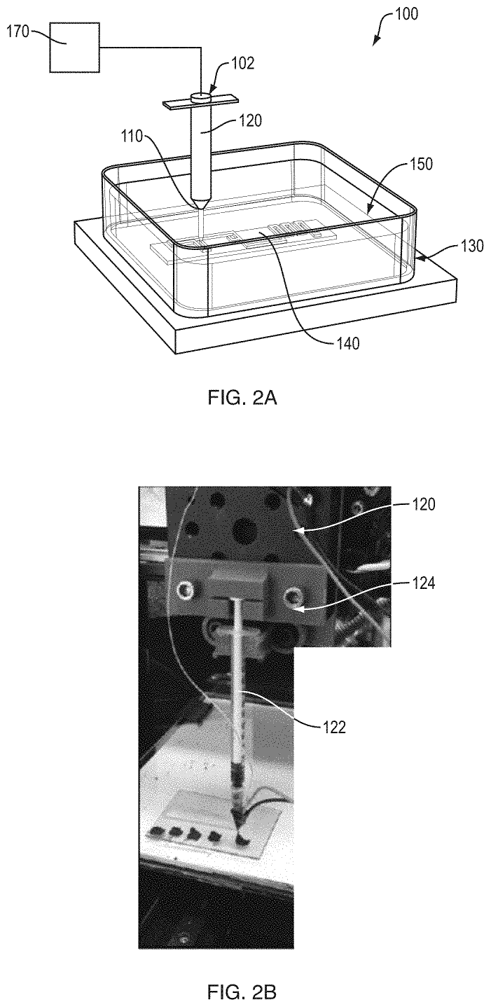

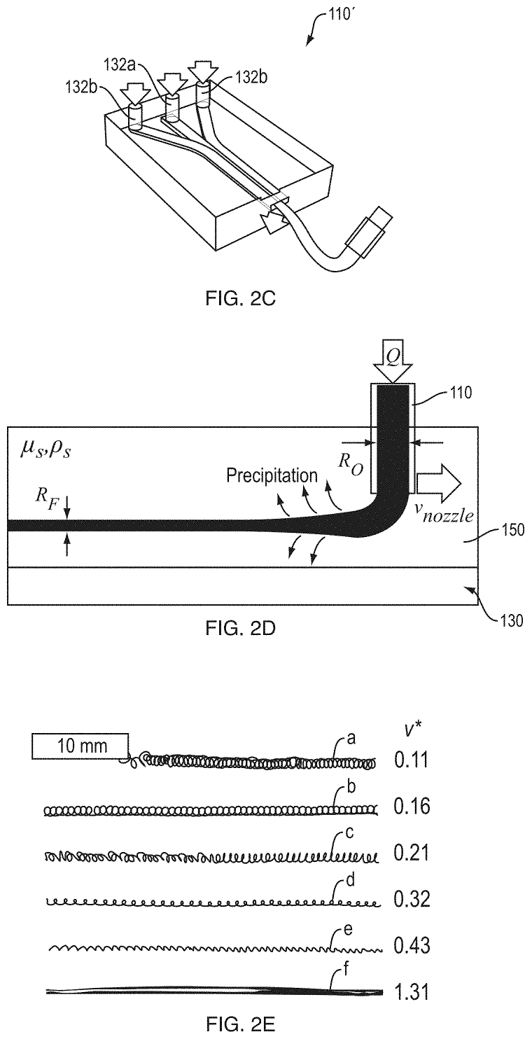

FIGS. 2A-2C illustrate an exemplary embodiment of a system of controlled drawing, which allows printing CNTs into fluids for the fabrication of planar and three-dimensional features and objects. Controlled drawing combines principles of fiber spinning with direct-write extrusion, or direct-write printing, to precipitate an input material into a fiber that is exposed to a fluid to form a solid structure. For example, in controlled drawing, a three-dimensional object can be printed by combining three-dimensional printing methods with external user control of flow regimes and external fields to tailor the microstructure of an ink deposited onto a substrate to manufacture solid CNT structures. As provided for herein, CNTs in a coagulant solution can self-align in extensional fluid flow, increasing strength and conductivity in that direction compared with unaligned CNTs, while also solidifying the objects. The control of CNT order and packing density can imbue macrostructures featuring complex 3D shapes with properties suitable for uses including high-current flexible wiring and field emitters. Further, applying direct-write printing principles to CNTs can also be used to reduce or eliminate defects and strength losses that occur when individual CNTs are bulk-formed into objects.

FIG. 2A provides one exemplary embodiment of a printer 100 set-up for controlled drawing. The printer 100 can provide motion control in the x, y, and z axes to influence a location and amount of ink being extruded. The illustrated embodiment includes a printhead 102 having one or more nozzles 110 and an extruder 120 for depositing materials used in the extruding process, but a person skilled in the art will recognize that various means of depositing materials onto a printing surface can be used. The nozzle(s) can be configured to move across one or more degrees of freedom to extrude materials therefrom at specific locations. In some embodiments, the nozzle can be a 27 gage, 0.2 mm nozzle, though the size can vary based, at least in part, on the desired diameter and/or aspect ratio of the precipitated fiber. For example, when the material includes CNTs, a diameter of a fiber can be at least about 0.01 millimeters and a length of the fiber can be at least about 5 millimeters such that an aspect ratio of the ink, which is a ratio of length to a diameter of CNTs used in the ink, is greater than about 1000. Inks that include CNTs having shorter lengths will have a higher concentration of CNTs to obtain the same effect. These materials can then be dissolved in a solvent that bonds as the solvent evaporates, thereby allowing rapid formation of solid structures. The solvent used can be water, but a person skilled in the art will recognize that other solvents having rapid evaporation capabilities can also be used, as discussed in greater detail below. Additional information about materials that can be used in conjunction with the printing devices, systems, and methods provided for in the present disclosure, including various deposition materials, solvents, surfactants, and materials to wash away materials that provided coagulation following deposition, are provided below, as well as throughout the present disclosure and those disclosures incorporated herewith.

In a bench model of the printer 100, the printer is a modified Makergear M2, where such modifications include the addition of an extruder 120 having a syringe 122 coupled thereto to enable the printer to extrude a liquid ink therefrom, a custom 3D-printed syringe holder 124, as shown in FIG. 2B, and a bath 130 for disposing the extruded ink therein. However, many different 3D printers and syringe extruders, or similarly capable components, can be used in conjunction with the present disclosures. Components of a printer can include, but are not limited to, an air pump for delivering inks through the nozzles, one or more drivers to advance one or more printheads on which one or more nozzles can be disposed, as well as a controller to control and/or operate, among other things, a draw ratio of the liquid ink dispensed from the syringe extruder, as discussed further below, a print path along which the printhead(s) are moved and/or components of the printer that help control the rate at which a solvent associated with the ink disposed in the printer evaporates, and/or the rate at which a material loses its ability to adhere to other layers by another means (e.g., thermoplastics or thermosets). Various chambers for housing materials to be printed can also be part of the printer. The printer 100 is able to move across an x-y plane to deposit material onto a surface. The movement of the printer 100 in the x-y plane is a capability of 3D printers, and thus a description of how it is able to move in the x-y plane is unnecessary since it is understood by those skilled in the art.

As described in greater detail below, a z-height of the printhead 102 can also be adjusted, thus allowing the printer 100 to print in three dimensions. A person skilled in the art understands how a 3D printer is able to move in a third plane to adjust a location of one or more nozzles 110 of the printhead 102, and thus further explanation is not provided herein.

One or more components of the printing system can have a variety of alternative geometries. FIG. 2C illustrates an alternate embodiment of a microfluidic nozzle 110′ used in the printing device. As shown, the nozzle 110′ can include one or more tubes or passages 132 formed therein to deliver various compounds through the nozzle 110′. Each tube 132 can extend throughout the length of the nozzle 110′ or terminate in a reservoir within the nozzle 110′ to mix the contents of each tube. For example, the input, or spinning dope, can be delivered through one of the tubes 132a while the fluid or coagulant is delivered through one or more of the other tubes 132b, as shown. The dope and the fluid can mix within the nozzle 110′ and travel through a remainder therethrough to produce a CNT fiber and evaporated solvent as a byproduct. The shape of the tubes 132a, 132b, the reservoir where tube contents are mixed, and/or the nozzle 110′ can influence the shape and/or the alignment of the material within ink and/or the fiber while the reaction is taking place. For example, the tubes 132a, 132b can be shaped and/or oriented to shape the extruded ink or the input traveling therethrough. When the input and the fluid react to coagulate the ink, whether within the tubes or at any location within the nozzle 110′, the shape of the location can influence the orientation and/or alignment of the precipitated fiber exiting the nozzle. In some embodiments, the nozzle 110′ can be broken up into several segments within the device—a segment to form the fiber, and additional segments that coat the fiber with another material for strength, conductivity, or sensitivity to an environmental parameter, in one or more stages, or, alternatively, delivering the fiber through multiple stages to solidify the fiber.

Materials that can be used in conjunction with the devices and systems provided for in the present disclosure, like the printer 100, are vast, and can depend on a variety of factors, including but not limited to the desired properties of the object being printed (e.g., objects having strong electrical conductivity, thermal conductivity, current-carrying capacity, and strength) and the desired use of the object being printed (e.g., a solid structure made up of CNTs). The present disclosures allow the materials being used to form a solid structure that includes robust, locally defined mechanics that can tailor the structure of freeform nanotube for fabrication of planar and three-dimensional features and objects.

In an exemplary embodiment of a controlled drawing printing process, one or more materials can be dissolved in a solvent to make a mixture of viscous fluid, sometimes referred to as the dope or the ink, that is deposited by the printer 100, and more specifically the nozzle(s) 110. The materials that make up the ink can be mixed with the solvent within the nozzle, as shown in FIG. 2C, or in advance such that the mixture is introduced through the printer 100 for extrusion.

A person having skill in the art will recognize that although the instant disclosure discusses printing systems, devices, and methods of printing with CNTs, the systems, devices, and methods generally discussed herein can be applied to a broad range of materials. For example, the materials deposited by the printer 100 can include a liquid ink that includes carbon nanotubes, but may include other materials in lieu of and/or in addition to carbon nanotubes, such as suspensions of elongated nano-particles and elongated micro-particles. These nano-particles and/or micro-particles can have a flexible, rod-like shape, wire-like shape, a rigid, rod-like shape, or an anisotropic prolate shape. Some non-limiting examples of materials that can be used can include Kevlar, nanocrystalline cellulose, cellulose nanocrystals, metallic nanowires, nanotubes, nanorods, carbon nanofibers, boron nitride nanotubes, microwires, such as chopped carbon fiber, cellulose fibers, metallic microfibers, and/or polymers with a rigid backbone, such as polyacrylonitrile. A combination of one or more of the above materials further including other fillers, such as active materials, and/or, for example, functionalized carbon nanotubes, which can make the resulting fibers or 3D objects sensitive to some environmental feature, and/or other compounds that are extensionally thickening in their extensional rheology that can allow the ink to “stretch,” as understood by one skilled in the art can also be included. In some embodiments, the ink can be modified to include CNTs along with a polymer that cures by alternate methods, e.g., interfacial polymerization, bulk reaction, and/or UV or thermal curing to allow printing of a solid structure with increased strength and toughness. The ink can then be ejected from the printer 100 through the nozzle 110 in the printhead 102 for precipitation into a fiber that is deposited onto at least one of a substrate, an object disposed on the substrate, or previously extruded ink, as discussed further below.

The ink used for printing can have a variety of concentrations. In one exemplary embodiment, the ink can include a concentration of CNTs that is approximately in the range of about 0.1% by weight to about 0.9% by weight of CNTs dissolved in an aqueous solvent, e.g., water, though in some embodiments the concentration of CNTs can be approximately in the range of about 0.3% by weight to about 0.8% by weight of CNTs, or have a concentration of about 0.75% by weight of CNTs. One skilled in the art will recognize that a larger concentration of CNTs in the ink prior to extrusion creates a denser ink which can be beneficial as a greater density of CNTs can contribute to greater conductivity. In some embodiments, bile acid can be added in addition to, or in lieu of, the solvent as a stabilizer of the liquid ink. A person having skill in the art will recognize that surfactants, polymerization inhibitors, and other compounds can be added to lower surface tension of the liquid ink and to prevent the ink from becoming undesirably sticky or insufficiently viscous.

In some exemplary embodiments, cellulose and cellulose acetate can be used for structural materials and 3D printing within the ink composition. The cellulose molecule can be a linear polymer with a repeating unit that includes two anhydroglucose rings, (C6H10O5)n where n=10000 to 15000, that can be linked by covalent bonds. Cellulose can a preferred material because it is the primary reinforcement phase of many biological organisms, including trees, plants, algae, some sea creatures, and bacteria, and is also the most abundant organic polymer on Earth.

One having ordinary skill in the art will appreciate that in some embodiments, cellulose acetate, which is a functionalized form of cellulose, can be used instead of cellulose. Both cellulose and cellulose acetate are biocompatible, biodegradable, pleasant to the touch and inexpensive, making them excellent choices for mass manufacture of wearables and implantable devices. Both molecules are also compostable, dry quickly, are shrink, mildew, and moth resistant, are washable or dry cleanable, and are easily dyed. Cellulose acetate differs from cellulose in that approximately ⅔ of the hydroxyl groups on the cellulose molecule have been replaced by acetate groups. While this can reduce the number of hydrogen bonds in the material and thus its tensile strength, the cellulose acetate can become soluble in acetone, which enables the 3D printing process described herein. Additionally, for applications in filtration or microfluidics, cellulose acetate is also hydrophilic, has high surface area, and absorbs organics, allowing it to be used to produce specially structured separation membranes or even implantable sensors/filtration devices. It is also strongly dielectric and can be used to produce actuators in prostheses, as well as in robotics or haptic interfaces.

A person skilled in the art will recognize that a plurality of streams of extruded ink can be extruded simultaneously. The process outlined herein is very economical because it is rapid and carried out under ambient conditions. Moreover, polymers such as cellulose and cellulose acetate are highly abundant while the solvent is both inexpensive and can be recycled. Also, it will be appreciated by one skilled in the art that the methods disclosed herein provide for massive parallelization of fiber printing through the use of multiple printheads.

The surface upon which the deposited materials can be printed can be any surface. In some embodiments, the printer 100 can print onto a substrate 140. The substrate 140 can be a circuit board, a power transformer, one of a plurality of electronic components, or a material that can be used to create or in conjunction with electronic components. The substrate 140 can be made of a substantially flat surface having its own x-y plane, though in some embodiments the substrate 140 or other object can have a more contoured surface(s). Further, because 3D printing necessarily results in an object having three dimensions, and because the present disclosures relate to additive manufacturing, printing also occurs onto material that has already been deposited, such as filament or other materials previously deposited by the printer 100. In some embodiments, the surface onto which the material is deposited is an adhesive surface (i.e., a surface that includes an adhesive material, either as a portion of the surface, or covers the entire surface).

A person skilled in the art will recognize that in direct-write printing, a printer builds and extrudes a material layer-by-layer that solidifies into the air, while in controlled drawing the layers can be printed into a solution for precipitation. In the illustrated embodiment, the printer 100 prints into the bath 130 having the substrate 140 immersed therein. The bath 130 can be positioned such that it is disposed in fluid communication with one or more of the nozzles 110 and the syringe extruder 120 to receive the liquid ink therein. The bath 130 can include a receptacle that defines a volume configured to hold an amount of a fluid 150 sufficient to immerse a portion of the substrate 140. A size and shape of the bath 130 can vary, and depend, at least in part, on the substrate or other object(s) onto which is being printed, the size and shape of the other components of the device or system with which the bath is being used, etc. For example, as shown, the bath 130 can have a substantially rectangular or even square shape, can be assize commensurate with the size of the printer 100, and can house one or more of the substrate 140, an object disposed on the substrate 140, previously extruded ink, and/or the fluid 150. In controlled drawing, the process is sufficiently scalable such the bath 130 can be large to support macrostructures being printed therein.

Referring back to FIG. 2A, the bath 130 can include a fluid 150 therein for forming the extruded ink into a solid structure(s). The fluid 150 can be a coagulating fluid or a destabilizing fluid, which coagulates by, for example, one of the following three mechanisms that can be used to pull the CNT, e.g., the alignable nanowire, solution ink into a solid form: (1) the fluid 150 being a nonsolvent for the CNTs, thereby causing them to precipitate on contact; (2) the fluid 150 preferentially solubilizing one or more surfactant stabilizers on the CNTs, thereby causing the CNTs to precipitate; and/or (3) the fluid 150 reacting with the CNT solution ink, thereby causing the CNTs to precipitate. Precipitation of the CNTs causes the CNTs to solidify.

Coagulation of printed CNT materials allows fiber-spinning-style printing while implementing direct-writing techniques to control various properties of the resulting solid structure as discussed below. The fluid 150 can include one or more compounds that promote solidification of the extruded ink. For example, in some embodiments, the fluid 150 can include an inert liquid having a coagulant disposed therein. Pure CNTs are not self-supporting, and require exposure to another substance, e.g., a coagulant, to achieve this quality. The coagulant can include water, an organic alcohol, such as ethanol, methanol, or propanol, and/or acids like hydrochloric acid or sulfuric acid, and so forth that solidify the extruded ink into a fiber that can be used to build the solid structure.

The solvent in the liquid ink mixture is selected such that it does not undergo a chemical reaction with the fluid 150. Rather, it will be appreciated that the coagulant strength, C*, of the fluid 150 can be varied based on the composition of the ink to ensure that the fluid 150 is miscible with or reactive with the solvent of the ink while being immiscible with the CNTs in the ink, though it may be miscible with additional particles in the CNT ink that stabilize the CNTs. For example, for a liquid ink that includes CNTs, a bile acid-based surfactant, and water, the fluid 150 can include an organic alcohol, acetone, and/or an acid, such as hydrochloric acid or sulfuric acid, to cause the CNTs to precipitate. Alternatively, in embodiments in which the liquid ink includes an acid as the solvent, the fluid 150 can include water. The miscibility of the fluid 150 in the solvent creates a fiber with a greater concentration of CNTs, while the immiscibility of the CNTs in the solvent ensures that the CNTs do not dissolve in the fluid 150 to reduce the concentration of CNTs in the precipitated fiber. The properties of CNTs depend at least on one or more of the CNT diameter, wall number, chirality, and/or purity. In some embodiments, fibers having concentrations approximately in the range of about 50% to about 80% CNTs can be produced using the above-described methods, which can form solid structures having strong electrical conductivity, thermal conductivity, and current-carrying capacity. In some embodiments, such as when the bath 130 is not used in the printer 100, the fluid 150 can be disposed on the substrate 140 and/or on the object disposed on the substrate.

In some embodiments, the fluid 150 can include compounds that are noncoagulants. Some non-limiting examples of such compounds can include inert liquids, such as soils and fluorinated solvents. For example, in the case of circuits, inert liquids can be used in the fluid 150 for actively cooling circuit boards. The inert liquid can serve as a protective medium in which circuits can be adjusted without affecting the actual function of the circuit. The inert liquid can be added to the coagulant in the fluid 150 when repairing a circuit board or adding one or more features to the circuit that is submerged in the fluid 150.

The ink begins to coagulate upon contact with the fluid 150. When the ink contacts the fluid 150, a packing density of the carbon nanotubes can increase, thereby precipitating the fiber to form a continuous, solid structure. The ink can begin to solidify instantaneously, or substantially instantaneously, once it contacts the fluid, meaning that solidification begins to occur no more than about 100 milliseconds. While solidification times can vary, formation of fibers in the presently disclosed methods occur more rapidly than during standard 3D printing where solidification occurs by other methods, and in some cases can be an entire order of magnitude faster, such as about 5 milliseconds. After the fibers have solidified, the resulting 3D solid structures can be self-stable or self-supporting, which differs from fibers formed by fiber-spinning, which are typically one-dimensional and cannot be formed into solid structures.

The above-described process of using the fluid 150 to precipitate the extruded ink, rather than freezing the extruded ink to solidify the CNTs to form solid structures, allows for printing of CNTs having high density and purity to produce solid structures that exhibit high alignment of CNTs and strong electrical properties, such as conductivity. The process further allows for superior strength, modulus, and density. In some embodiments, the specific conductivity exhibited by solid structures printed using the above-described methods can be approximately in the range of about 20 times to about 50 times that of any carbon nanomaterial due to the high purity and alignment of the solid structure. Moreover, the solid structures can have up to about 25% of the specific conductivity of metals such as copper, silver, and so forth, with some structures having a specific conductivity of up to about 33% or even about 50% of the specific conductivity of these metals. By aligning individual CNTs during extrusion and solidifying them quickly using the fluid, superior alignment is maintained, thereby resulting in CNT macrostructures having a high conductivity and strength.

The ink precipitated after contacting the fluid 150 in controlled drawing is a solid thread having substantially no breaks. As discussed above with respect to continuous extrusion, a person skilled in the art will understand that instances in which the nozzles stops and starts, or changes direction may be desirable, and thus the term “continuous” can encompass situations in which there is a break in the fiber when the desired solid structure calls for the break, or when the fiber inadvertently breaks. Fibers can be layered on one another to form the solid structure. It will also be appreciated that the solid structure can be composed of multiple continuous fibers or a single continuous fiber.

The printer 100 can include a controller 170. The controller 170 can be configured to adjust one or more parameters of the draw ratio, such as a flow rate of the extruded ink, a temperature of the extruded ink, a concentration of the liquid ink, e.g., adjusting a ratio of solvent to nanomaterial in the mixture, a height and/or a velocity of one or more of the nozzles 110, or a velocity of the at least one of the substrate 140, an object disposed on the substrate, or previously extruded ink to produce CNT macrostructures having superior properties. Moreover, in some embodiments, the controller 170 can adjust one or more parameters of the printing process to vary properties of the extruded ink making up the solid structure. For example, the controller 170 can control one or more of a temperature, humidity, or oxygen content of at least one of the bath 130, the fluid 150 disposed in the bath, and/or an environment of or surrounding the bath 130 to regulate formation of the solid structures.

Despite the similarities in fiber spinning and direct-write printing, one skilled in the art will recognize, for example, that fiber-spinning is a steady state process in which a single length of continuous fiber is extruded. The fiber is deposited in a single dimension, and due to the consistency of the fiber, the fibers are one-dimensional, and the fibers are typically not used to build three-dimensional structures. Direct-write printing, on the other hand, includes a method of extruding ink that can have an unsteady state. For example, in direct-write printing, the printhead 102 can move in the x, y, and z axes, as discussed above, to print three-dimensional structures. Rather than continuously dispensing, direct-write printing can selectively extrude ink therefrom at specific intervals and/or locations to shape the desired solid structure, as described further below.

The systems, devices, and methods disclosed herein can allow a user, for instance by way of the controller 170, to control the microstructure of the resulting solid structure being printed by controlling a draw ratio for printing of the solid structure, as given below:

$$Dr = \frac{{V}_{nozzle}}{Q / π {R}_{o}^{2}} {=}^{Δ} {v}^{*}$$

where ν* is the drawing ratio, V_{nozzle} is the velocity of the nozzle, Q is the flow rate input of the ink (volume/time), and Rₒ is a radius of the nozzle. The output velocity of the extruded ink from the nozzle 110 is given below: [symbol]
The draw ratio therefore measures flow rate divided by area, which provides an output velocity of the ink versus the velocity of the nozzle, as shown by the above equations.

FIG. 2D illustrates an exemplary embodiment of a fully continuous printing process in which the ink is extruded into the bath 130 having fluid 150 therein. As shown, the nozzle 110 is moving left to right through the bath 130 and extruding the ink therein at a flow rate Q. The ink is extruded from the nozzle 110 having a radius of Rₒ, which contains a mixture of the CNTs and the solvent. As the extruded ink contacts the fluid 150, the extruded ink begins to solidify, thereby forming the precipitated fiber that can be used to form the solid structure. During solidification, the solvent exits the extruded ink into the bath 130, which can thin out the precipitated fiber as the nozzle continues to extrude ink. As the nozzle 110 travels relative to the bath 130 and the amount of time the extruded ink spends contacting the fluid 150 increases, increased amounts of solvent exit the extruded ink, until the precipitated fiber having a radius RF is formed. It will be appreciated that either of the flow rate Q and/or the velocity of the nozzle, V_{nozzle}, can be adjusted to alter the form of the extruded ink, and thereby the resultant precipitated fiber, as described in detail below.

A person skilled in the art will recognize that the draw ratio can predict that a falling thread of material will coil in predictable ways depending, at least in part, on its height and the velocity by which it moves relative to the substrate underneath. By varying the parameters of the draw ratio, the CNTs can be extruded from the ink into a series of coiled patterns. FIG. 2E illustrates the relationship between the draw ratio and the coiling behavior of several precipitated fibers. The labeled draw ratios of each of the coiled fibers include 0.11 (a), 0.16 (b), 0.21 (c), 0.32 (d), 0.43 (e), and 1.31 (f). Because of the speed of the coagulation, the coils do not fuse together when they land on top of one another, which allows for pulling apart that can be useful mechanically by being able to print an object that has embedded strain. Further, coiled structures can exhibit electric properties of inductors and/or solenoids and could find application as strain sensors, which one skilled in the art will appreciate has stronger properties than uncoiled counterparts.

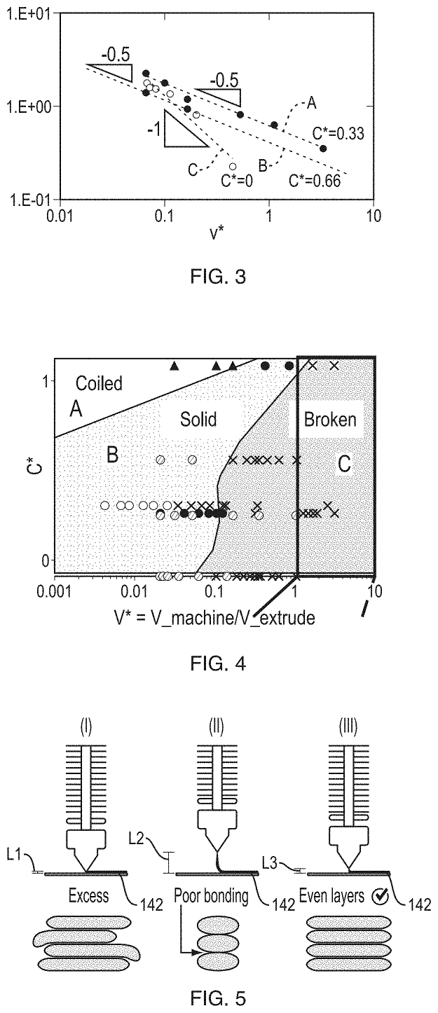

In some embodiments, coiling behavior of the CNTs can be varied by varying the composition of the fluid 150, and specifically the coagulant strength, C*, of the coagulant contained therein. For example, the coagulant strength of the coagulant can range between a strong or fast coagulant (C*=1) and a weak coagulant or noncoagulant (C*=0). The coagulant strength can help control the coiling behavior of the solid structure exposed to the coagulant. Coagulants and noncoagulants can be mixed in various proportions recognized by one skilled in the art, in view of the present disclosures, to create a coagulant having a coagulant strength that corresponds to a desired shape of the solid structure. For example, the draw ratio can be used to determine the relationship between speed of the nozzle and a radius of the fiber precipitated from the extruded ink, as shown in FIG. 3.

More specifically, FIG. 3 illustrates the relationship between the draw ratio and radius of the fiber for fibers precipitated from an extruded ink into fluids of various values of C*. The labeled coagulant strengths of the three fluids into which ink is extruded include 0.33 (A), 0.66 (B), and 0 (C). As shown, for each coagulant strength of the fluid 150, as the draw ratio increases, the radius of the fiber extruded therefrom has a smaller radius, e.g., thinner. Further, for fluids containing some degree of coagulant strength, e.g., C* values of 0.33 and 0.66, as the speed of the nozzle steadily increases, the radius of the extruded fiber steadily decreases. Thinner fibers are more easily align in the final solid structure and can thus be used to improve the conductivity and other properties of bulk CNTs that are typically lost when CNTs are provided in bulk.

Maintaining the relationship between the velocities in the draw ratio can dictate the form of the extruded ink, and thereby the resultant solid structure. For example, when the draw ratio is too high, e.g., the velocity of the nozzle is significantly faster than the velocity of the ink, such as the extruded ink having a draw ratio of 1.31 in FIG. 2E, the extruded ink is being excessively stretched because the nozzle 110 is traveling faster than the speed of extrusion. Excessively high draw ratios can result in precipitated fibers that are thinner than desired, and in some instances, create fibers having a broken configuration, as discussed in greater detail below. Conversely, when the draw ratio is too low, e.g., the velocity of the nozzle is significantly slower than the velocity of the ink, the extruded ink can become excessively compressed due, at least in part, to the ink being extruded faster than the nozzle moves. Compression of the ink can result in precipitated fibers that are excessively coiled and/or thicker than desired, causing longer drying times and insufficient solidification time that can cause layers to bleed into each other. Further, at a low draw ratio, the extruded fibers may have little to no alignment, but at faster speeds, alignment can increase due to the higher draw ratio and fast coagulation. Alignment can also increase due to the thinner fibers being printed, which allows these fibers to be disposed more closely with other CNT fibers, thereby making a more continuous structure to prevent loss of conductivity and strength in spaces between CNTs. Suitable draw ratios for use in conjunction with the systems, devices, and methods provided for herein can be approximately in the range of about 0.1 to about 5.

The impact of excessively high draw ratios on extruded fibers is shown in greater detail in FIG. 4. As shown, the fibers are extruded having a coiled (A), solid (B), or (C) broken configuration. One skilled in the art will recognize that adjusting the draw ratio can be used to control coiling behavior. For example, as shown in FIG. 2E, for values of draw ratios (v*) closer to zero, a distance between coils is minimal, but as the draw ratio increases, the extruded fiber becomes less coiled and starts to resemble a straight line. As the speed of the nozzle increases, the spaces between extruded inks can increase, thereby decreasing coiling of the extruded ink. At draw ratios of one or higher, the extruded fibers may no longer be continuous, instead breaking with at least some regularity, regardless of the coagulant strength of the fluid. At coagulant strengths below 1, the morphology, e.g., the degree of coiling, of the fiber can vary. For example, in some embodiments, the morphology of the fiber can depend on the coagulant strength of the fluid 150 to determine whether the fibers are coiled or solid, with coagulant strengths of approximately 0.75 or higher producing coiled configurations.

As shown, the draw ratio tends to have a greater effect on the morphology of the fiber for most coagulant strengths of the fluid 150. In some embodiments, the length of the broken fibers can be proportional to the velocity of motion. This can be used to estimate the strength of the fibers at the time of breaking by calculating the applied shear stress and measuring the length of the fiber fragments. It will be appreciated that while solid, continuous fibers are discussed herein as the desired end product to form the solid structure, in some embodiments, coiled and/or broken fibers can also be the desired end product, and thus draw ratios and other parameters can be selected accordingly to achieve such desired results.

By controlling the draw ratio, the controlled drawing process differs from fiber spinning in that in conventional fiber spinning processes, the nozzle would spin as fast as possible to print long fibers of a material, e.g., Kevlar. In fiber spinning, the nozzle is continuously spun to make a linear, long fiber, that can be measured in meters. In controlled drawing, the draw ratio could be adjusted to tune microstructures that are on the order of nanometers, micrometers, and/or millimeters to produce small solid structures having high alignments. Moreover, in controlled drawing, the nozzle 110 can move relative to the printing surface, e.g., the substrate 140, linearly, but also can change directions at various angles to allow printing of corners and/or other non-linear structures. A person skilled in the art will recognize that non-linear structures can refer to structures that have one or more bends and/or curves formed therein. For example, the nozzle 110 can extrude ink while traveling in a first direction and then reverse direction or travel at a perpendicular angle, an oblique angle, and/or another angle between 0 and 360 degrees relative to the first direction while continuing to extrude the ink therefrom. The extruder 120 can be toggled between an “on” configuration in which the one or more nozzles 110 continuously extrude the ink therefrom, and an “off” configuration in which the one or more nozzles 100 do not extrude ink therefrom. The ability to toggle as well as change direction while extruding can produce highly customizable structures in two-dimensions and three-dimensions in which the nanostructures can be substantially aligned, that are not available by fiber spinning alone at least because fiber spinning does not feature a moving nozzle relative to a printing surface. It will be appreciated that the ability to print nonlinear structures can be beneficial, for example, in printing and/or manufacturing circuit boards and other electronics.

Moreover, the steady state nature of controlled drawing can allow for printing without draw effects immediately after being switched to the “on” configuration or after turning a corner during extrusion. Unlike in industry-scale fiber spinning, in which some time must pass before alignment of extruded fibers can be controlled after the nozzle changes direction or is turned on, in controlled drawing the desired alignment of extruded fibers can be obtained immediately or substantially immediately, i.e., in the time it takes coagulation to occur. Therefore, unlike in fiber spinning, there is no need to discard extruded ink until the draw ratio is set, which allows the precipitated fibers to be truly continuous even when the nozzles 110 fluctuate between being “on” and “off.” It will be appreciated that a change in direction can occur both in the “on” and “off” configurations, that is, while the printhead is extruding ink and while no ink is extruded.

The controller 170 can control additional parameters of the printer 100 in controlled drawing to modify the fibers being formed from the extruded ink. For example, variations of nozzle height and its effect on the solid structure are illustrated in FIG. 5. As shown in (I), when the nozzle 110 is positioned at a first distance L1 from a printing surface 142, the extruded ink can be excessively adhesive when it reaches the surface and adhere to the underlying layer. Excess fibers are printed as a result and may not be sufficiently solidified prior to the next layer being printed thereon, which can cause overlap between layers of extruded ink, as shown, which can compromise solidification of the fibers and cause it to be unstable and not self-supporting. Alternatively, as shown in (II), when the printhead can be positioned at a second distance L2 from the printing surface 142, the solvent may largely be evaporated by the time the extruded ink reaches the printing surface, and is therefore dried. Dried extruded ink can prevent bonding between the formed fibers as a first layer of fibers has already solidified prior to the second layer being deposited thereon. Regulating nozzle height to a distance L3, as shown in (III), L3 being between L1 and L2, can ensure that each layer of extruded ink are printed evenly and the desired amount of bonding occurs.

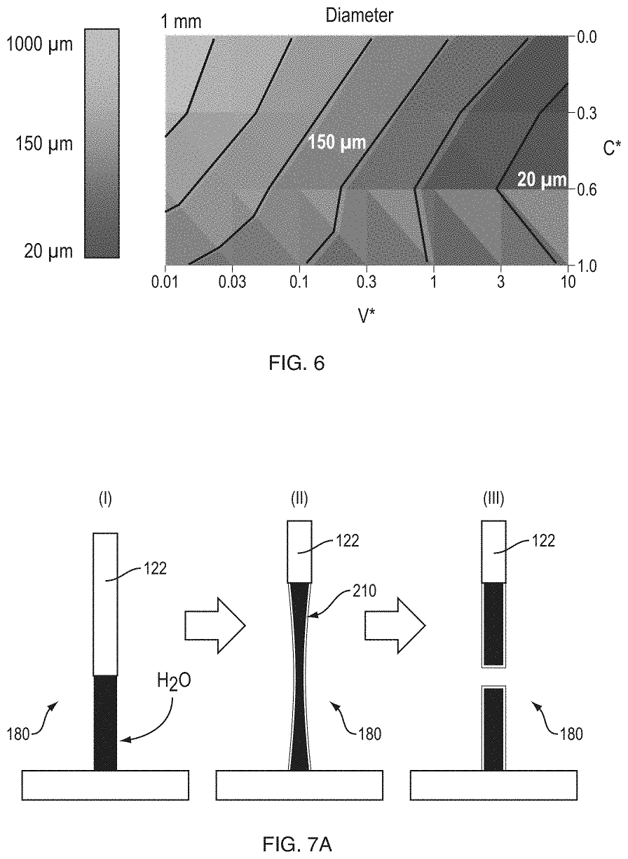

FIG. 6 illustrates a contour plot of the fiber diameter with respect to draw ratio and coagulant strength. As shown, as coagulant strength and draw ratio increase, the diameter of the extruded fibers decreases. For example, fiber diameters can range from fibers having about 1 mm diameters at a draw ratio of about 0.01 in a noncoagulant, to fibers having about a 20 micrometer diameter in the strongest coagulants (C*=1) at a draw ratio of about 10. In forming the solid structure, the fluid 150 is mixed based on the coagulant strength that would produce the desired fiber diameter. It will be appreciated that, in some embodiments, the diameter of the extruded ink that precipitates the fiber can be smaller than a diameter of the nozzle being used due to the solvent evaporating from the extruded ink, thereby conserving mass.

In some embodiments, the ink can be printed into the bath 130 and/or onto the substrate 140 in the absence of the fluid 150. For example, the ink can be extruded from the nozzle 110 in a process akin to three-dimensional printing, in which the ink is extruded from the printer and printed onto a dry, or substantially dry, substrate. Rather than printing into a printing bath, in some embodiments, the fiber can be printed into free space, though it will be appreciated that printing on a substrate is better suited when printing electronics. Once the ink is extruded, the fluid 150 can be added to promote coagulation of the fiber. A person skilled in the art will recognize that the extruded ink can be laid out to dry in a variety of configurations, e.g., the desired shape of the solid structure, after which the fluid 150 can be added to specific locations along the fiber to promote solidification and adhesion between layers. Additional modifications to the printing systems, devices, and methods discussed herein can include customization of the devices disclosed herein to include a nozzle for extrusion that finely controls the initial reaction of the ink with the fluid 150 before extruding onto the print bed, wherein the shape of the device is neatly tailored to apply nearly pure extensional flow to the forming fiber, thereby coagulating the fiber in a neatly controlled environment even while the motion of the nozzle along the print bed may be more dynamic. This modification can be made to a standard 3D printer, where the printer can tailor the fiber properties (e.g., density, conductivity, strength, composition of the ink by changing a percentage of substances mixed, and so forth), where the fibers are then printed immediately, or collected and later laid down into their desired shape. Alternatively, the devices can be used to control the forces on the forming fiber, not via a coagulant, but using another kind of reaction, such as polymerization, or a geometry of the fiber, to form a fiber with controlled properties. These and similar modifications utilize principles of the wet fiber spinning method can be used to draw out tailored structures, and use the nozzles to apply a controlled strain such that the printer does not print into liquid. The fibers, and solid structures, produced by these methods can be used in many more applications will be possible beyond wiring, including improved heat pipes, radiation shielding, and strong lightweight elements for actuators and light load-bearing elements.

Acid-Supported Printing

In an alternate embodiment of the printing method, CNTs can form solid structures by precipitating an extruded ink containing a mixture of CNTs and one or more acids into the fiber and/or exposing the extruded ink to temperature to promote a phase change to precipitate the fiber. Except as indicated below, and as will be readily appreciated by one skilled in the art, the structure and function of the systems, devices, e.g., the printer, and methods is substantially the same as that of the systems, devices, and methods described above, and therefore a detailed description is omitted for the sake of brevity.

In acid-supported printing, the extruded ink is precipitated into a fiber in free space, similar to that of direct-write printing. The ink used in these methods can include a single-walled carbon nanotube (SWCNT) in a mixture of oleum and p-toluenesulfonic acid. The ink is shear thinning, and the rapid evaporation of the solvent further increases the viscosity of the extruded ink after ejection, which results in excellent dimensional control of printed parts. The ink is extruded through a printer that is similar to the printer described above. In some embodiments, related to the systems described above as well as the ones now being described, the printer can include a heating element, e.g., a resistive heater, attached, or disposed proximate to, one or more of the nozzles. The resistive heater can be used to keep the acid of the ink above its melting temperature to ensure that the ink stays in its liquid state. A person skilled in the art will recognize that there can be a small amount of extensional flow in the system due to the shape of the needle of the syringe.

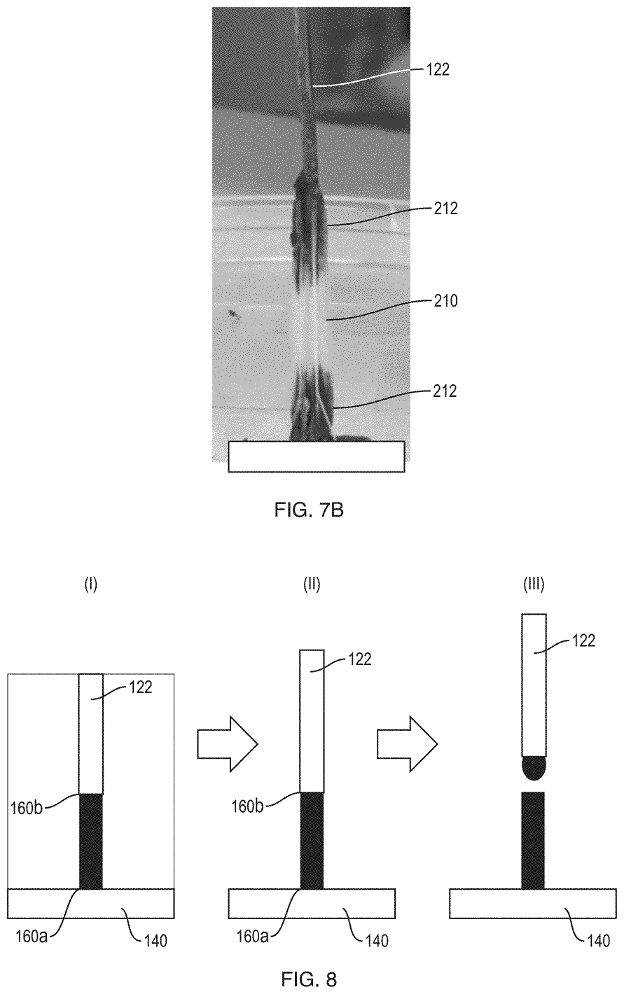

The ink can solidify in a variety of ways once extruded. FIG. 7A illustrates an exemplary embodiment of a reaction-controlled process for forming the solid structure in which the liquid ink containing CNTs is disposed into a gaseous environment 180 such that one or more components of the liquid reacts with the surrounding atmosphere so as to increase the rigidity of the material dispensed. The CNT-containing liquid is similarly dispensed with respect to a substrate such that the deposition and construction of an object maybe planar or three-dimensional. This process can occur independent of temperature and thus room temperature, e.g., 25 degrees Celsius, or any other temperatures can be maintained. As shown in (I) of FIG. 7, the acid in the ink can react with water vapor in the environment to form a monohydrate. The monohydrate has a higher melting point than the acid and can cause a skin to form on the outside of the extruded ink, as shown in (II). When solidifying a liquid ink that contains CNTs in a p-toluenesulfonic acid solvent via water vapor reaction to form a p-toluenesulfonic (pToS) monohydrate, which is solid at room temperature, the solid nature of the structure depends, at least in part, on reaction time. For example, for reaction times of the reaction with the surrounding atmosphere can range from approximately in the range of about 0.5 seconds to about 60 seconds, which can be orders of magnitude longer than precipitation of fibers via controlled drawing due to the absence of a coagulant. A person skilled in the art will recognize that these longer reaction times can cause separation between the CNTs and the monohydrate, as shown in (III), due, at least in part, to the CNTs being not as soluble in the monohydrate as in the pure acid, and discussed in greater detail below.

FIG. 7B illustrates the structure of the monohydrate 210 formed on a distal end of a syringe 122 as a result of the reaction in (II) in greater detail. As shown, the pToS monohydrate 210 solidifies with consistent symmetric growth such that the CNTs 212 are disposed on the extremities of the solid structure, while the middle of the monohydrate structure is made up of pure pToS that connects the CNTs to one another. As the reaction persists, the pure pToS can fracture, thereby forming the structure shown in FIG. 7A (III). A person skilled in the art will recognize that the solid structures consistently grow from and fracture in the center at the pure pToS.

FIG. 8 illustrates an exemplary embodiment of a temperature-controlled process for forming the solid structure. In the temperature-controlled process, the syringe 122 is heated to a temperature that is above that of the substrate 140 onto which the extruded ink is deposited. For example, in a room temperature environment, the syringe 122 can be heated to a temperature approximately in the range of about 35 degrees Celsius to about 40 degrees Celsius, while the substrate 140 can be maintained at a temperature approximately in the range of about 10 degrees Celsius to about 20 degrees Celsius. A person skilled in the art will recognize that these temperature values were chosen due to the nature of the acid in the liquid ink to ensure that the acid remains in the liquid phase in the heated syringe, and can fluctuate depending, at least in part, on which acid is chosen, among other factors known to those skilled in the art in view of the present disclosures. It will be appreciated that the temperature values can vary depending on the environment, though maintaining a temperature difference of at least about 15 degrees Celsius between the syringe 122 and the substrate 140 can facilitate the temperature-controlled precipitation of the fibers.

As shown in (I), the extruded ink contacts the substrate 140 such that a first end 160a of the extruded ink contacts the substrate 140 while the second end 160b remains disposed in the syringe 122. The temperature difference between the first and second ends 160a, 160b can cause the first end 160a to undergo a phase change into a solid while the second end can remain a liquid, as shown in (II). As the syringe 122 separates from the substrate 140, additional layers of the extruded ink solidify until the liquid and solid phases separate, as shown in (III).

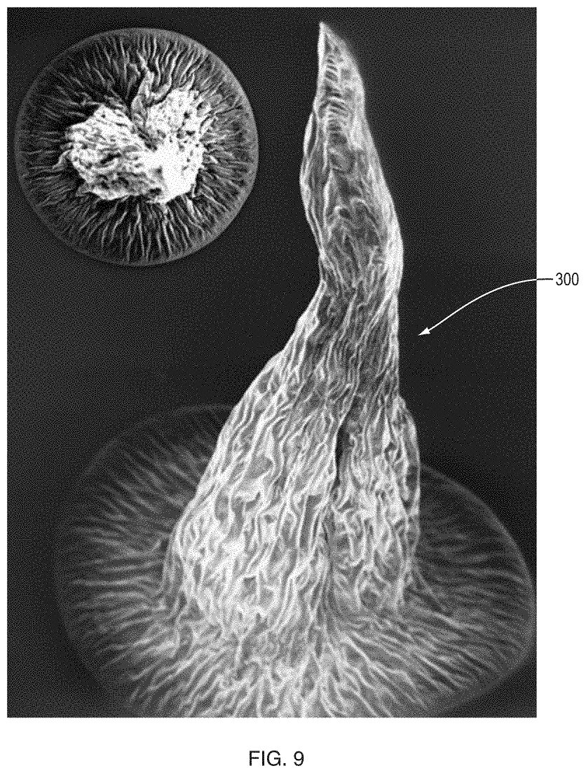

A person skilled in the art will appreciate that the overall fiber diameter, as well as the resulting shape of the solid structure, can be controlled by controlling the draw ratio, which can thereby control the competing effects of the solidification mechanisms affecting the solid structure. Controlling the draw ratio can allow printing structures in three different regimes—small melt pools such as blobs, extended structures with a necking pinch-off that terminate at a point, and making extended lines and freeform solid structures. For example, the necking pinch-off at the top of the solid structure can be useful for making field emitters and high-powered microwaves because the sharp tip can promote high conductivity of the material. In some embodiments, the necking pinch-off can be used to create design structures such as the hat 300 illustrated in FIG. 9. FIG. 9 shows a surface wrinkled by capillary forces pulling inward when the printed object fully dries. Large fibrils of nanotubes are aligned, which results in high inter-tube contact area, and gives rise to high conductivity values of the solid structures. The ability to control the location in which the ink is extruded, can allow for formation of free-form solid structures having unique shapes. For example, the free-form macrostructure can be printed to terminate in a sharp tip, as shown.

The illustrated and described systems, devices, methods, configurations, shapes, and sizes are in no way limiting. A person skilled in the art, in view of the present disclosures, will understand how to apply the teachings of one embodiment to other embodiments either explicitly or implicitly provided for in the present disclosures. Further, a person skilled in the art will appreciate further features and advantages of the present disclosure based on the above-described embodiments. Accordingly, the disclosure is not to be limited by what has been particularly shown and described, except as indicated by the appended claims. All publications and references cited herein, including the aforementioned document and provisional application, are expressly incorporated herein by reference in their entirety.

1. A method of extruding inks that comprise suspensions of at least one of elongated nano-particles or elongated micro-particles, comprising:
extruding an ink through a nozzle of a printing device into a fluid and onto at least one of a substrate, an object disposed on the substrate, or previously extruded ink, the ink comprising a mixture of at least one of nano-particles or micro-particles and a liquid, and the fluid comprising one or more materials; and
moving the nozzle in one or more degrees of freedom with respect to the substrate while extruding the ink into the fluid,
wherein the ink coagulates after it contacts the fluid such that the ink forms a solid precipitate.

2. The method of claim 1, wherein extruding the ink through a nozzle of a printing device into the fluid further comprises continuously dispensing ink such that the ink forms a continuous thread upon coagulation.

3. The method of claim 1, further comprising adjusting a draw ratio associated with the extruded ink such that the overall fiber diameter is controlled.

4. The method of claim 3, further comprising adjusting the draw ratio or other parameters such that the nanostructures can be substantially aligned in the direction of motion of the nozzle relative to the substrate.

5. The method of claim 3, wherein adjusting a draw ratio comprises adjusting at least one of a flow rate of the extruded ink, a temperature of the extruded ink, a velocity of the nozzle, or a velocity of the at least one of a substrate, an object disposed on the substrate, or previously extruded ink.

6. (canceled)

7. (canceled)

8. (canceled)

9. (canceled)

10. The method of claim 1, wherein the ink contains carbon nanotubes, and the fluid comprises one or more of an alcohol, a ketone, or an acid.

11. The method of claim 1, wherein the ink contains cellulose nanocrystals, and the fluid comprises a salt solution.

12. The method of claim 1, wherein the ink contains elongated nanostructures that are electrically conductive.

13. The method of claim 1, wherein the ink contacts the fluid within the nozzle.

14. The method of claim 13, further comprising controlling the shape and alignment of the material within the solid precipitate while the ink is forming the solid.

15. (canceled)

16. A method of extruding inks that comprise suspensions of at least one of elongated nano-particles or elongated micro-particles, comprising:
extruding an ink through a nozzle of a printing device into a fluid bath, the ink comprising at least one of nano-particles or micro-particles and a liquid, and the fluid bath having a coagulant disposed therein to solidify the ink to form an object,
moving the nozzle relative to the fluid bath to define a form of the object; and
adjusting one or more of a velocity of the extruded ink through the nozzle or a velocity of the nozzle relative to the fluid bath.

17. (canceled)

18. The method of claim 16, wherein a diameter of the extruded ink is smaller than a diameter of the nozzle from which the liquid is extruded.

19. (canceled)

20. The method of claim 16, wherein the ink is extruded into the fluid bath continuously throughout the movement of the nozzle.

21. A printing system, comprising:
an extruder having one or more nozzles, the extruder being configured to dispense a liquid ink out of the one or more nozzles, the ink comprising a mixture of at least one of nano-particles or micro-particles and a solvent; and
a bath defining a volume in which a fluid is configured to be disposed therein, the bath being in fluid communication with the extruder such that the bath is configured to receive the liquid ink.

22. The system of claim 21, wherein the fluid is configured to cause the liquid ink to coagulate to form a solid structure.

23. (canceled)

24. The system of claim 21, further comprising a controller configured to adjust at least one of a flow rate of the liquid ink, a velocity of the one or more nozzles, or velocity of a location disposed in the bath, the location being where the liquid ink is being dispensed to control the draw ratio of the liquid ink dispensed from the extruder.

25. (canceled)

26. (canceled)

27. The system of claim 21, wherein the extruder is configured to dispense the ink out of the one or more nozzles in a continuous manner.

28. (canceled)

29. The system of claim 21, wherein the ink comprises a solution of carbon nanotubes in water that approximately ranges from about 0.1% by weight to about 0.9% by weight of carbon nanotubes relative to the total weight of the solution.

30. (canceled)

31. The system of claim 21, wherein the fluid is configured to be disposed within the one or more nozzles such that the liquid ink reacts with the fluid within the nozzle.

32. The system of claim 31, where the nozzle is configured to control the shape and alignment of the material within the precipitate formed after the liquid ink reacts with the fluid.
